(19) United States
(12) Patent Application Publication
(10) Pub. No.: US 2026/0362757 A1
(43) Pub. Date: Nov. 12, 2026

(54) METHODS FOR CONTROLLING HOLE SPIN QUBITS

(71) Applicant: National Research Council of Canada, Ottawa (CA)

(72) Inventors: Sergei STUDENIKIN, Orleans (CA); Maksym MYRONOV, Rugby (GB); Cyril HNATOVSKY, Ottawa (CA)

(21) Appl. No.: 18/593,400

(22) Filed: Mar. 1, 2024

(51) Int. Cl. H10D 48/40; G06N 10/40; H10D 48/00; H10D 62/832

(52) U.S. Cl. CPC H10D 48/40; G06N 10/40; H10D 48/3835; H10D 62/832

(57) ABSTRACT

A method of controlling a hole spin qubit in a semiconductor substrate, the method comprising: applying voltages to a plurality of gates to form two tunnel-coupled quantum dots (CQD) comprising a first quantum dot confining a single hole and a second quantum dot configured to stimulate spin transitions in the first quantum dot and configured for readout of a spin qubit state in the first quantum dot; applying a local electric field to control a g-factor of the single hole; applying global magnetic field across the semiconductor substrate to cause splitting of spin energy levels of the qubit; and applying a microwave field of defined frequency and voltage pulses to manipulate the qubit.

### FIELD

Aspects of the disclosure relate to methods and systems for quantum computing.

### BACKGROUND

The superconducting quantum computing is one of the most developed quantum computing technology platform in terms of the number of functional qubits in one quantum circuit relies on operating the quantum processing units at temperatures below 0.02 K (20 mK), which requires the use of special cryogenic refrigeration techniques and expensive custom-made refrigerators with sophisticated wiring and noise filtering in order to manipulate and preserve the qubit states. On the other hand, the electronics to control the superconducting qubits cannot operate at mKs and needs to be placed outside the refrigerators at a much higher temperature, usually room temperature. Taking into account that each individual qubit is connected to the control electronics with several wires and a useful quantum computer requires around one million addressable qubits, the heat flow and dissipation from the control wires would eventually thermally overload any conceivable refrigeration system working at 20 mK.

This fundamental physical and technological problem can be overcome in quantum computing based on the semiconductor platform, specifically using hole spin qubits created in compressively strained germanium on silicon (cs-GoS). Such qubits can be operated at temperatures above 2 K.

### SUMMARY

In one of its aspects, a qubit formed in a semiconductor substrate, the qubit comprising: two tunnel-coupled quantum dots (CQD) comprising a first quantum dot confining a single hole and a second quantum dot configured to stimulate spin transitions in the first quantum dot;
a first plurality of gates configured to create a plurality of confinement potential regions, the first plurality of gates further configured to create a CQD array containing the qubits; and
wherein the CQD array is formed within the semiconductor substrate;
a second plurality of conducting gate electrodes for applying voltages to the first quantum dot of the CQD, wherein a first set of conducting gate electrodes and a second set of conducting gate electrodes of the second plurality of conducting gate electrodes are connected to split control gates of a first quantum dot in each qubit of the array, wherein the first set of conducting gate electrodes and the second set of conducting gate electrodes of the second plurality of gate electrodes configured to apply an electric field to the first quantum dot of CQD to control the g-factor of the single hole;
the qubit is configured to have its spin energy levels split upon application of a global magnetic field applied perpendicularly to the semiconductor surface;
the first plurality of electrodes configured to apply a microwave field in order to stimulate the transitions in the first quantum dot; and
the qubit is configured to be manipulated upon application of voltage pulses applied to a select set of gate electrodes of the second plurality of gate electrodes in the presence of a microwave field.

In another of its aspects, a method of controlling a hole spin qubit in a semiconductor substrate, the method comprising:
applying a voltage to a first plurality of gates to form two tunnel-coupled quantum dots (CQD) comprising a first quantum dot confining a single hole and a second quantum dot configured to stimulate spin transitions in the first quantum dot and configured for readout of the spin state of the hole confined in the first quantum dot;
applying a local electric field vertically to control a g-factor of the single hole;
applying global magnetic field perpendicularly to the semiconductor substrate to cause splitting of spin energy levels of the spin qubit; and
applying a microwave field of defined frequency and voltage pulses to manipulate the spin qubit.

In another of its aspects, an array of addressable hole spin qubits in a semiconductor substrate, the array comprising:
each qubit comprises two tunnel-coupled quantum dots (CQD), wherein a first quantum dot confines a single hole and a second quantum dot is empty and configured to stimulate spin transitions in the first quantum dot at the fundamental electric dipole spin resonance (EDSR) frequency and sub-harmonics of the fundamental EDSR frequency, and wherein a plurality of confinement QD potential regions is created by a first plurality of gates configured to contain the qubits;
a second plurality of conducting gate electrodes for applying voltages to the first quantum dot of the CQD, wherein a first set of conducting gate electrodes and a second set of conducting gate electrodes of the second plurality of conducting gate electrodes are connected to split control gates of a first quantum dot in each qubit, wherein the first set of conducting gate electrodes and the second set of conducting gate electrodes of the second plurality of gate electrodes configured to apply an electric field to the first quantum dot of CQD to control the g-factor of the single hole;
the qubit is configured to have its spin energy levels split upon application of a global magnetic field applied perpendicularly to the semiconductor surface;
the first plurality of electrodes configured to apply a microwave field; and
the qubit is configured to be manipulated upon application of voltage pulses applied to a select set of gate electrodes of the second plurality of gate electrodes in order to tune g-factors of selected qubits into the resonance with the microwave excitation frequency.

In a further aspect, there is provided a technology to create hole spin qubits with an extra-large separation (larger than 0.3 meV and 10-40 GHz MW in the frequency units) between their spin energy levels in quantum dots (QDs) in compressively strained germanium on silicon (cs-GoS) and a method is provided to control such spin qubits using electronics operating in the 10-40 gigahertz (GHz) range which is easily achievable by the current telecommunication technologies. Thus, the method describes steps for building low-error semiconductor quantum computing modules suitable for the operation at temperatures above 2 K and, importantly, how to control them using standard microwave technologies.

The qubit operation is based on using EDSR sub-harmonics (i.e., not the main harmonic) for efficient spin rotations mediated by multiple tunnelling transitions between the spin states of the CQDs which occur during the microwave excitation at the resonant sub-harmonic frequencies. Namely, a single hole is localized in the first QD and the other empty QD of the CQD unit cell is used as a functionalizing auxiliary element to affect the spin of said single hole qubit. In this case, the spin rotation rate of the hole is substantially increased due to the tunnel coupling with the auxiliary QD on both the main EDSR frequency and at its sub-harmonics, which leads to coherent spin operations on a 10-nanosecond time scale. Therefore, a fundamental microwave hardware limitation is overcome as control of qubits with an extra-large separation between their spin energy levels becomes possible by means of standard microwave electronics.

In another aspect, there is provided methods for controlling semiconductor spin qubits with an extra-large separation (up to 1 meV and 10-40 GHz MW in the frequency units) between their spin energy levels, in the presence of a magnetic field, which is required for low-error operation above 2K using standard electronics in the 10-40 GHz frequency range. Spin qubits with an extra-large separation between the spin energy levels allow their low-error operation at temperatures exceeding 2 K, which opens the way for building large-scale quantum computing architectures inside standard inexpensive cryogenic refrigerators. In particular, the methods relate to operating hole spin-qubits in cs-GoS at temperatures exceeding 2 K. The unique combination of cs-GoS physical properties ensures that the required separation between the spin energy levels (i.e., Zeeman splitting energy) is easily achievable using relatively weak magnetic fields generated by compact and inexpensive permanent magnets and the energy splitting of the resultant qubits can be tuned by means of a perpendicular electric field. The ability to control spin qubits at elevated temperatures is achieved by using sub-harmonics of EDSR in a spin qubit system consisting of two CQDs.

The methods described herein are based on EDSR sub-harmonics to operate cs-GoS hole spin qubits with an extra-large separation between their spin energy levels. As a result, cs-GoS quantum computing modules with a low error rate operation at temperatures above 2 K become possible.

### BRIEF DESCRIPTION OF THE DRAWINGS

Several exemplary embodiments of the present disclosure will now be described, by way of examples only, with reference to the appended drawings in which:

FIG. 1 shows an example of the cross-sectional view of a heterostructure and fabricated gated Hall-bar device, with its source (S) and drain (D) ohmic contacts and gate (G) stack;

FIG. 2 shows an optical microscopy image of a plan view of the gated Hall-bar shown in FIG. 1;

FIG. 3 shows an example schematic of the cross-sectional view of an addressable spin qubit device with QD1 (left) being occupied with a single hole, and the auxiliary QD2 (right) being empty;

FIG. 4 shows an example of a simplified version of an addressable linear (1D) chain of spin qubits;

FIG. 5 shows an example schematic of an addressable 2D spin qubit array, wherein each spin qubit consists of two coupled quantum dots (CQD); and the addressability is achieved by means of applying unique voltages to vertical and horizontal address lines Vᵢ and Vⱼ;

FIG. 6a shows an example how the CQDs in FIG. 5 can be created by means of two pluralities of gates V1 and V2;

FIG. 6b shows an example of how a predetermined vertical electric field can be applied to QD1s in FIG. 6a by means of addressable split gates, in which the vertical electric field is determined in the first approximation by a combination of voltages applied to vertical gates V3 and horizontal gates V4 connected to the split gates; and the split gates are placed on top of QD1s in FIG. 6a;

FIG. 6c shows how auxiliary QD2s in FIG. 6a are controlled by means of gates V5. Gates V5 are placed on top of QD2s in FIG. 6a;

FIG. 7a shows an example of an addressable 2D array of spin qubits, wherein each spin qubit consists of three CQDs: quantum dot QD1, QD2 and QD3; and QD4 is an auxiliary one attached to each spin qubit and is used only for the quantum information transfer sequence in the vertical direction; in which QD1, QD2, QD3 and QD4 are created by means of gates V1 and V2;

FIG. 7b shows how a predetermined vertical electric field is applied in an addressable way to QD1s in FIG. 7a by means of gates V3 and V4, in which the vertical electric field is determined in the first approximation by a combination of voltages applied to split gates connected to vertical gates V3 and horizontal gates V4; and the split gates are placed on top of QD1s in FIG. 7a;

FIG. 7c shows an example of how QD2s, QD3s and QD4s in FIG. 7a are controlled by means of gates, wherein gates V5 control QD2s and gates V6 control QD3s and QD4s. Gates V5 are placed on top of QD2s in FIG. 7a, and gates V6 are placed on top of QD3s and QD4s in FIG. 7a; and

FIG. 8 shows a flowchart with example steps of a method of controlling a hole spin qubit in a semiconductor substrate, the hole spin qubit comprising two tunnel-coupled QDs.

### DETAILED DESCRIPTION

The following detailed description refers to the accompanying drawings. Wherever possible, the same reference numbers are used in the drawings and the following description to refer to the same or similar elements. While embodiments of the disclosure may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the following detailed description does not limit the disclosure. Instead, the proper scope of the disclosure is defined by the appended claims.

Moreover, it should be appreciated that the particular implementations shown and described herein are illustrative of the invention and are not intended to otherwise limit the scope of the present invention in any way. Indeed, for the sake of brevity, certain sub-components of the individual operating components, conventional data networking, application development and other functional aspects of the systems may not be described in detail herein. Furthermore, the connecting lines shown in the various figures contained herein are intended to represent exemplary functional relationships and/or physical couplings between the various elements. It should be noted that many alternative or additional functional relationships or physical connections may be present in a practical system.

The fundamental physical and technological problems faced by the superconducting quantum computing platformed mentioned in the BACKGROUND section above can be overcome in quantum computing based on the semiconductor platform, specifically using hole spin qubits created in compressively strained germanium on silicon (cs-GoS). In this case, the separation between the spin energy levels of the hole spin qubits can be made so large that temperatures above 2 K will not affect their quantum states. Quantum computing at temperatures above 2 K is a game changer since qubits can be stored and operated in commercially available conventional refrigerators whose cooling capacity at 2 K is orders of magnitude higher than that of dilution refrigerators used for superconducting quantum computers. Hence, quantum computing based on cs-GoS is technologically feasible in terms of scalability, mass-production and operation of the pertinent quantum circuits. In addition, compatible cold electronics can be created on large-size cs-GoS wafers operating at cryogenic temperatures, which will dramatically reduce the number of control wires required to operate cs-GoS quantum computers by means of user interfaces kept at room temperatures.

However, operating spin qubits with a very large separation between the spin energy levels presents another major challenge of its own. In order to initialize, operate and store such low-error qubits, the frequency of the applied microwave signals must be in the terahertz (THz) range, which considerably exceeds the limits of existing microwave electronics. Additionally, it is impossible to deliver THz signals to quantum circuits stored in refrigerators at cryogenic temperatures.

The spin degree of freedom of an electron or hole provides a natural two-state system that can be used for the realization of qubits. In 1998, Loss and DiVincenzo proposed to use the spin degree of freedom of individual electrons confined in semiconductor quantum dots (QDs) for quantum computing [1]. Since then, QD-based electron spin qubits have been produced in semiconductors such as gallium arsenide (GaAs) [2], [3] and silicon (Si) [4]. Additionally, hole spin qubits were also demonstrated in double QDs fabricated from germanium (Ge) hut wires [5] and in double QDs in planar Ge [6].

Currently, silicon is the main semiconductor material in which small 1D arrays of electron spin qubits have been demonstrated. Spin qubits in graphene, carbon nanotubes, 2D-materials and many other nanowire-type structures are positioned at the very surface and, as a consequence, are strongly influenced by unpredictable surface effects. Such spin qubits cannot be fabricated on large substrates and lack reproducibility. As a result, quantum circuits based on them are not scalable by definition.

The initialization, manipulation and readout of electron or hole spin qubits in semiconductor QDs are currently realized by applying DC-pulses and high-frequency microwave bursts to the conducting surface gates placed near the qubits [8], [9]. The frequency of the control microwave bursts is equal to the EDSR frequency. The latter is determined by the separation between the qubit spin energy levels, which, in turn, is directly proportional to the applied magnetic field and the effective g-factor of the free charge carriers confined in the QD. At the moment, only the main EDSR harmonic is used to operate single-spin qubits.

The main drawbacks of electron spin qubits produced in Si QDs using advanced CMOS technology can be summarized as follows: (i) the small effective electron g-factor (i.e., ≈2) in Si requires storing and operating the spin qubits below 1 K. The Zeeman spin energy splitting E_{Z} of electron spin qubits in Si at easily achievable magnetic fields of ≈1 Tesla (T) is thus E_{Z}/k_{B}≈0.6 K in the temperature units, where k_{B} is the Boltzmann constant. The temperature at which qubits can be stored and operated should be smaller than E_{Z}/k_{B}, as it was shown that the coherence time of Si spin qubits operated at ≈1 T dropped exponentially when the surrounding temperature exceeded 0.4 K [10]; (ii) the effective g-factor of conduction band electrons in Si is not sufficiently tunable for building addressable arrays of spin qubits based on the g-factor tunability. For example, in Ref. [11] the demonstrated tunability was only ≈0.002% due to the Stark effect. To tackle this obstacle, a micro-magnet technology based on creating a non-uniform magnetic field near the neighboring QDs to make their EDSR frequencies slightly different was proposed [12]. However, it is very challenging to create a sufficiently large magnetic field gradient between closely positioned QDs, especially in Si where the neighboring QDs are just a few tens of nanometers (nm) apart. Therefore, (iii) only a small number of addressable qubits can be produced in Si using the micro-magnet technology.

Moreover, (iv) electron spin qubits in Si show poor uniformity, which makes scaling-up of quantum processors based on them very challenging. The poor uniformity is mainly due to the harmful effect of valley degeneracy in Si where each of the two spin levels in qubits arises from the specific nature of the conduction band minima of Si. Microscopic strain fields and other surface effects at the atomic scale remove the degeneracy and thus cause additional splitting of the valley and spin levels. Because of the fluctuating nature of the surface effects, the magnitude of the splitting also fluctuates [8] making the resultant qubits irreproducible. To this end, it is also impossible to accurately calculate the qubit's characteristics.

The large effective mass of conduction band electrons in Si, which puts strong constraints on the dimensions of the QDs (i.e., less than 20 nm). As a consequence, the maximum depth of the resultant spin qubits under the surface is also less than 20 nm. The properties of such shallow qubits (v) are very difficult to control and reproduce because of the unpredictable 3D character of their shapes, strain fields and surface charge states whose properties fluctuate both in time and space [8].

Recently, hole spin qubits in cs-GoS have attracted significant interest due to the unique properties of cs-GoS, which will be described below. Namely, a programmable four-qubit quantum processor based on hole spins in cs-GoS has been recently demonstrated [7]. The hole spin qubits in cs-GoS do not suffer from the above limitations [13]. Indeed, hole spin qubits in cs-GoS have the following critical advantages over electron qubits in Si: (i) holes in cs-GoS have a very large effective g-factor, in the range from 15 to 25 [14] (and possibly more), which ensures a very strong spin energy splitting in magnetic fields below 1 T. Importantly, such relatively weak magnetic fields can be generated by permanent magnets; (ii) the effective hole g-factor can be tuned within a wide range (i.e., 15-25) by means of an electric field applied perpendicularly to the surface by a conducting surface gate, which provides addressability of the resultant hole spin qubits and allows the use of optimized quantum computing algorithms to operate them.

The cs-GoS materials system possess unique properties that are not simultaneously found in any other semiconductors. These properties include (iii) a small effective mass of the holes (can be as low as about 0.035 m₀ in cs-GoS vs about 0.3 m₀ in Si; m₀ is the mass of a free electron), which can be engineered by changing the strain in the Ge epilayer confining the holes, and (iv) a large Rashba-type spin-orbit coupling, which is necessary for fast quantum operations of spin qubits. Hole spin qubits in cs-GoS (v) have a well-defined 2D geometry and their properties are fully defined by the material stack and therefore these quantum dots can be accurately calculated before fabrication. In addition, the g-factor is also largely defined by the material stack (not by QD lateral gates or uncontrollable fluctuations like in Si devices). These properties are desirable for the realization of large-scale quantum computers (qubit modules). This combination of parameters can be engineered by the growth process and vertical electric field applied to a plurality of gates.

The current limitation of hole spin qubits with an extra-large separation between the spin energy levels, which allows their operation at temperatures above 2K, is the impossibility to manipulate such qubits using the main EDSR harmonic because it would be in the THz frequency range. Electromagnetic excitations of such frequency cannot be generated using current microwave technology and, importantly, delivered into cryostats via conducting wires and coaxial cables.

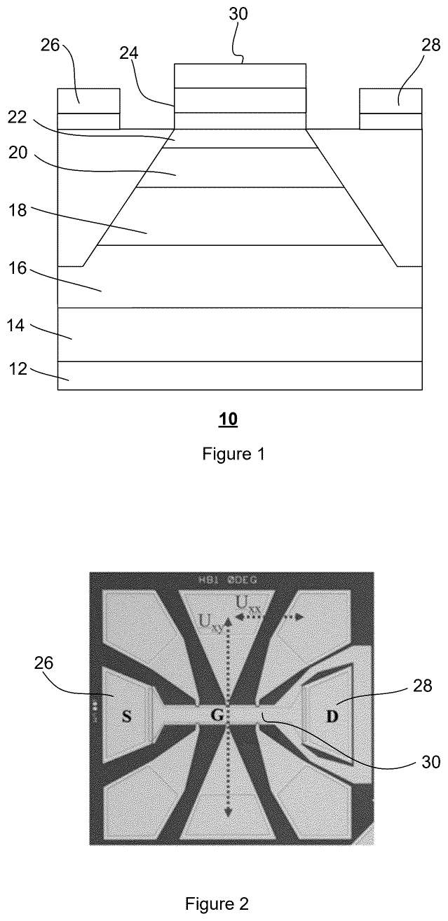

Looking at FIG. 1, there is shown a cross-sectional view of a heterostructure and fabricated gated Hall-bar structure 10, and FIG. 2 shows a microscopy photo image of a gated Hall-bar fabricated using standard UV lithography, dry etching, and thin-film deposition techniques.

As can be seen in FIG. 1, the structure 10 comprises a substrate 12, such as a silicon substrate, upon which relaxed graded buffer layers 14, 16 are formed. Buffer layer 14 may comprise graded regions of silicon-germanium, Si₁₋ₓGe₁₋ₓ, where x is in the range of 1 to 0.7. A quantum well (QW) 18, such as an undoped, strained germanium QW, is formed on top of the relaxed grade buffer layer 16, such that holes accumulated by the negative gate voltage are confined in the undoped QW 18. The QW 18 is positioned below a capping layer 20, such as a Si_{0.15}Ge_{0.85} cap epilayer in this example having a thickness in the range of about 50 nm to about 1000 nm (e.g., 100 nm in the example case) and a thin Ge cap interface 22 and an aluminium oxide (Al₂O₃) gate dielectric 24 and within the gate dielectric, including source (S) ohmic contact 26, drain (D) ohmic contact 28 and gate (G) conductive layer 30, each comprising a metallic gold layer and a titanium layer (in this example), or possibly a transparent layer made of a metal oxide film.

Other embodiments may include fewer layers (e.g., fewer buffer layers and/or no capping layer) or more layers (e.g., additional spacer and/or doped layers below QW layer) or different layers (e.g., formed with different semiconductor materials, formulations, and/or dopants). The layers may be implemented with any suitable layer thicknesses and other desired layer parameters, using established semiconductor processes (e.g., metal organic chemical vapor deposition, molecular beam epitaxy, photolithography, or other such suitable processes), and may be graded (e.g., in linear or step fashion) to engineer carriers' effective mass and g-factor using lattice constant mismatch between neighboring layers or otherwise lattice diverse materials. In general, the specific layers and dimensions of the structure will depend on factors such as the desired device performance, fab capability, and semiconductor materials used.

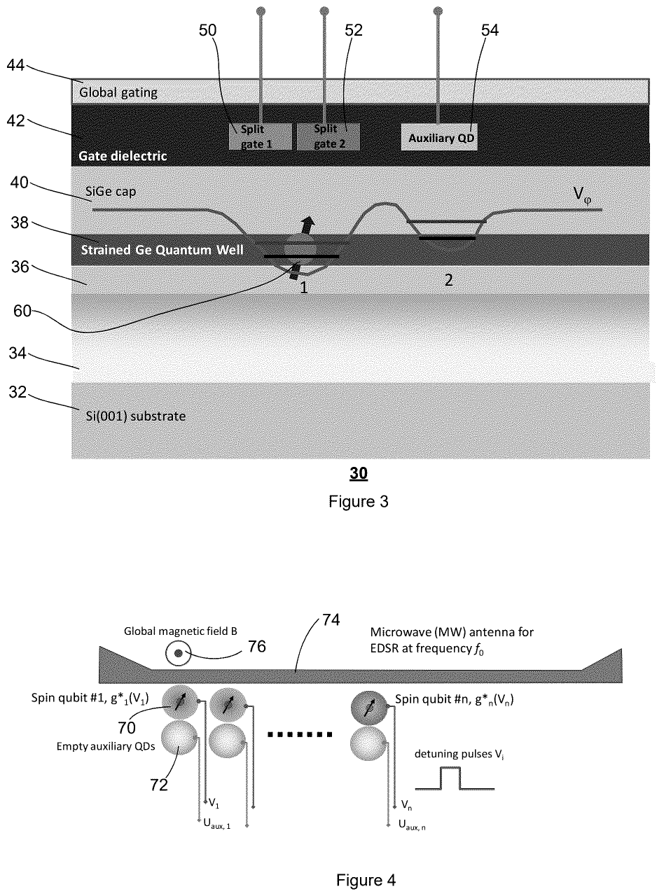

FIG. 3 shows a cross-sectional view of an example addressable hole spin qubit structure 30. In one example, the structure 30 comprises a substrate 32, such as a silicon substrate, upon which relaxed grade buffer layers 34, 36 are formed. A QW 38, such as an undoped QW in cs-GoS, is formed on top of the relaxed grade buffer layers 34 and 36, such that holes accumulated by negative gate voltages are confined in the undoped QW 38. The QW 38 is positioned below a SiGe capping layer 40, and gate dielectric 42 and global gating electrode 44. Embedded in the gate dielectric 42 is split gate₁ 50, and split gate₂ 52 to form split-gate cross bars for the qubit addressability, as will be explained below, and the auxiliary QD gate 54.

In operation, specific voltages and/or voltage pulses are applied to the split gate₁ 50, split gate₂ 52 respectively to tune the effective g-factor of the hole confined in QD1 in a such way that the Zeeman energy of the specific qubit becomes equal to the microwave photon energy and therefore spin transitions can be forced via the EDSR process or its sub-harmonics. As can be seen in FIG. 3, QD 60 is positioned substantially below the semiconductor surface in the range between about 50 nm to about 1000 nm and gates thereby substantially minimizing noise and substantially increasing coherence time. The presence or absence of a hole in QD 60 is measured by a charge sensor circuit [9].

FIG. 4 shows a simplified version of a linear chain of spin qubits, wherein each qubit consists of two CQDs, 70 and 72, respectively. QD 70 contains a single hole whereas QD 72 is empty, i.e., it contains no free charge carriers. QD 72 serves as a non-linear auxiliary element to stimulate hole spin transitions at the fundamental EDSR frequency and sub-harmonics of the fundamental EDSR frequency. The qubit operation is based on using EDSR sub-harmonics for efficient spin rotations mediated by multiple tunnelling transitions between spin states of two CQDs 70 and 72 which occur during the microwave excitation at the resonant sub-harmonic frequencies. In this case, the spin rotation rate of the hole inside QD 70 is substantially increased due to the tunnel coupling with the auxiliary QD 72 on both the main EDSR frequency and at its sub-harmonics, which leads to coherent spin operations on a 10-nanosecond time scale. Therefore, a fundamental microwave hardware limitation is overcome as control of qubits with an extra-large separation between their spin energy levels becomes possible by means of standard microwave electronics and wiring. Reference [15] provides a theoretical model for using sub-harmonics of EDSR mediated by multiple tunnelling transitions during microwave excitation to manipulate the Zeeman-split spin states of two GaAs CQDs. A spin qubit based on two CQDs can be addressed by applying control voltages Vₙ to QD 70 in order to tune the hole g-factor in and out of the sub-harmonic EDSR frequency, and auxiliary voltages U_{aux, n} to tune the energy difference between QDs 70 and QDs 72 for improved sub-harmonic EDSR operation. Accordingly, the empty auxiliary QDs 72 serve as auxiliary external elements to produce new functionalities, i.e., to make sub-harmonic EDSR possible, and thereby allow for manipulation of the hole spin in QD 70. The spin rotation frequency f₀ at EDSR sub-harmonics is given by f₀=gᵢ(Vᵢ)μ_{B}B/hN, where N is the sub-harmonic number, μ_{B} is the Bohr magneton, B is the perpendicular magnetic field applied to the spin qubit, and h is Planck's constant. Alternatively, the main harmonic may be used, then, the device will require lower temperatures to operate.

In one example, a global magnetic field 76 is applied to the sample, electromagnetic microwave (MW) excitation is generated by a MW strip-line antenna 74, and selected spin qubits formed by CQDs 70 and 72 can be tuned in the EDSR condition by tuning the g-factors of holes confined in QDs 70 using pulsed gate voltages Vₙ applied to QDs 70.

In another example, the global microwave field, instead and/or in addition of using a strip-line antenna 74) may be generated by means of KTaO₃ single crystals combined with a bulk microwave excitation.

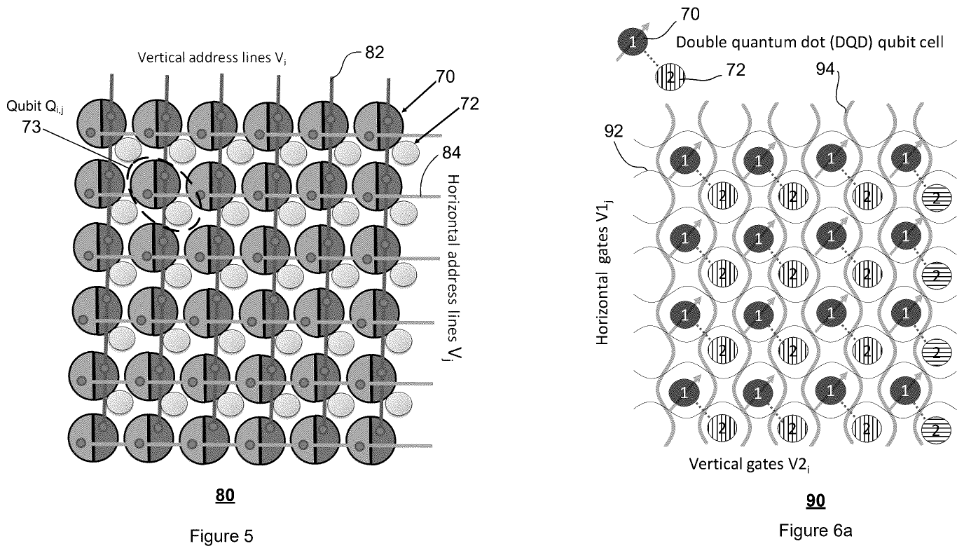

FIG. 5 shows a portion of the interior volume of the example addressable spin qubit structure 80 comprising a plurality of spin qubits Q_{i,j} 73 each of which consists of a QD 70 and an auxiliary QD 72. In the example shown, the addressable spin qubit structure 80 includes a first subset of control lines 82, such as conducting gate electrodes Vᵢ (i is a positive integer) oriented along the x-axis of a cartesian coordinate system that intersect a second subset of control lines 84, such as conducting gate electrodes Vⱼ, (j is a positive integer) oriented along the y-axis of the cartesian coordinate system. In the example shown, voltage signals Vᵢ and Vⱼ are applied to the conducting gate electrodes 82 Vᵢ and conducting gate electrodes 84 Vⱼ, respectively.

The hole g-factor of each spin qubit Q_{i,j} 73 is determined by the unique combination of the split gate voltage Vᵢ+Vⱼ, such that only one qubit Q_{i, j} can have the correct g-factor, i.e., g_{i,j}(Vᵢ+Vⱼ), for EDSR or sub-harmonic EDSR manipulation by the microwave field. Voltages Vᵢ and Vⱼ are synchronized to address and manipulate specific qubits Q_{i,j} 73 within the array 80.

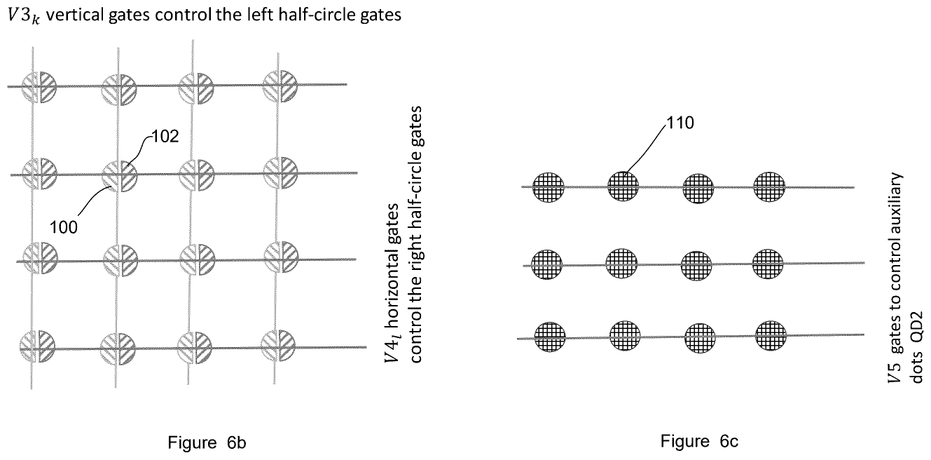

FIG. 6a shows an example of a double quantum dot architecture of spin qubits 90. This double quantum dot (DQD) architecture has five gate layers offset by thin insulating layers. An example of a 4×4 qubit matrix is presented in FIG. 6a. Pluralities of gates V1 92 and V2 94 are used to create the scalable DQD array 90. Each unit cell (i.e., a spin qubit) consists of a double quantum dot QD1 70 and QD2 72, in which QD1s 70 are occupied with a single hole. The initialization is produced from the peripheral contacts [3]. The QD2s 72 are empty and are used i) as auxiliary elements for inducing efficient spin rotations at the EDSR frequency and its sub-harmonics, ii) for serving as a latched readout element and iii) as a charge memory register of the qubit state after the quantum algorithm has been completed [9]. The final state of the hole spin in QD1 70 is converted into a single-hole charge state stored in QD2 72. The latched readout sequence is described in [9]. During this process the hole is transferred to QD2 72 only if the hole spin is up. The hole remains in QD1 70 (i.e., QD2 72 being empty) if the hole spin is down. The results are stored in the array of QD2s 72. The array of QD1s 70 also stores the result that is the logical “NOT” of the result stored in the array of QD2s 72. Therefore, these two QD arrays can be used together for error correction and increased fidelity. The results stored in QD1 70 and QD2 72 arrays are transferred to the peripheral classical electronics using a protocol that moves the stored charges step by step along the vertical lines 94 using V1 gates, similar to the protocol used in charge-coupled devices (CCDs).

FIG. 6b shows how a predetermined vertical electric field can be applied to QD1s 70 in FIG. 6a by means of split gates 100 and 102. The vertical electric field is determined by a combination of voltages applied to vertical gates V3 and horizontal gates V4. Split gates 100 and 102 are placed on top of QD1s 70 in FIG. 6a. Split gates 100 and 102 are top gates that are divided into two semi-circle portions with a crossbar connection to V3 and V4 to make them individually addressable, resulting in two sets of address lines. Generally, the split top gates 100, 102 are possible only with the cs-GoS materials system due to the small hole effective mass. The above split-gate approach also makes the number of gates to be proportional to the square root of the number of quantum dots, which allows for scalability of the quantum circuit. Voltage V3ₖ is applied to vertical gates to control the left half-circle gates 100, while voltage V4ₗ is applied to the horizontal gates to control the right half-circle gates 102. As such, V3 and V4 gates perform addressable manipulations of individual qubits because the hole g-factor of QD1s 70 is a function of V3ₖ+V4ₗ, which is denoted by

$${g}_{kl}^{*} ( V {3}_{k} + V {4}_{l} ) .$$

Addressable manipulations of individual qubits are performed using a microwave electromagnetic field with a frequency

$${f}_{MW} = {g}_{kl}^{*} ( V {3}_{k} + V {4}_{l} ) {μ}_{B} B / h$$

and by applying voltage pulses to V3ₖ and V4ₗ. Therefore, only QD1s 70 with

$${g}_{kl}^{*} ( V {3}_{k} + V {4}_{l} )$$

being in resonance with the microwave field are manipulable, whereas the other QDs are out of resonance and therefore immune to interacting with the microwave field.

FIG. 6c shows how auxiliary QD2s 72 in FIG. 6a are controlled and tuned by means of gates V5. Circular gates 110 are connected to gates V5 and placed on top of QD2s 72 in FIG. 6a. QD2s 72 are not controlled individually. Gates V5 are also configured for read-out of the quantum information by applying voltages to them in a step-by-step manner to move the charges in the vertical direction to single hole charge sensors positioned at the periphery, similar to common CCD read-out protocols.

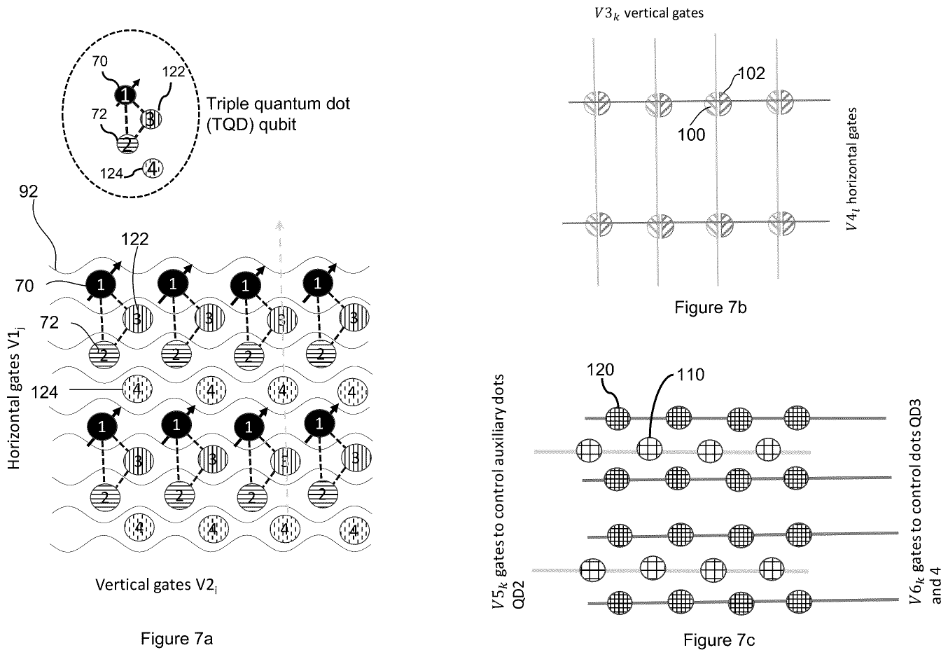

FIG. 7a shows an example of addressable and scalable 2D array of spin qubits, wherein each spin qubit consists of three CQDs: QD1 70, QD2 72 and QD3 122. QD4 124 is attached to each spin qubit and, together with QD3 122, is used only for quantum information transfer in the vertical direction. This triple quantum dot (TQD) architecture has six gate layers offset by thin insulating layers. An example of a 4×2 qubit matrix is presented in FIG. 7a.

QD1s 70, QD2s 72, QD3s 122 and QD4s 124 are created by means of gates V1 and V2. QD1 70, QD2 72, QD3 122 form a quantum computer qubit cell, whereas QD 124 is empty and used only in the charge-information transfer step. QD1 70 contains a single hole. QD2 72 and QD3s 122 are auxiliary empty QDs. QD2 72 enables single-spin rotations via EDSR, including EDSR sub-harmonics. QD3 122 is used for latched read-out and storage of the spin state of QD1 70. The latched spin-readout technique converts spin information into a charge state which can be read out by standard charge sensing techniques [17]. Single charges stored in the registers formed by QD3s 122 are transported along the chain of QDs 122 and 124 in the vertical direction using the V1 and/or V6 plurality of gates [16].

FIG. 7b shows how a predetermined vertical electric field is applied to QD1s 70 in FIG. 7a by means of gates V3 and V4. The vertical electric field is determined by a combination of voltages applied to split gates 100 and 102 connected to vertical gates V3 and horizontal gates V4, respectively. Split gates 100 and 102 are placed on top of QD1s 70 in FIG. 7a. V3 and V4 gates perform addressable manipulations of individual qubits because the hole g-factor of QD1s 70 is a function of V3ₖ+V4ₗ. Addressable manipulations of individual qubits are performed using a microwave signal with a frequency

$${f}_{MW} = {g}_{kl}^{*} ( V {3}_{k} + V {4}_{l} ) {μ}_{B} B / h$$

and by applying voltage pulses to V3ₖ and V4ₗ. Therefore, only QD1s 70 with

$${g}_{kl}^{*} ( V {3}_{k} + V {4}_{l} )$$

have correct g-factor and therefore can be manipulated, whereas the other dots are out of resonance with the microwave field.

FIG. 7c shows how QD2s 72, QD3s 122 and QD4s 124 in FIG. 7a are controlled by means of gates, wherein gates V5 control QD2s 72 and gates V6 control QD3s 122 and QD4s 124. Gates V5 are placed on top of QD2s 72 in FIG. 7a. Gates V6 are placed on top of QD3s 122 and QD4s 124 in FIG. 7a.

As such, the gates are modified to reach the single qubit addressability. Also, a qubit may be formed from two or more quantum dots for extended functionalities, such as the ability to operate at higher temperatures using subharmonics, including latched readout, and information transfer to classical peripheral circuits, similarly to how it is done using standard charge-coupled device (CCD) technology. In one example, there is provided latched spin readout architecture of the triple quantum dot (TQD) in which quantum information converted in charge state of the third QD, and transferring the result to the peripheral classical processing electronics.

In the TQD design for more reliable operations, the third QD is used as a separate latching spin-readout register, whose operation is described in [9].

A weak microwave field for resonant spin-qubit manipulations is applied globally using a microwave antenna, or via a subset of gates for a period of time during which quantum algorithms are executed. During the read-out and transfer steps the microwave excitation is turned off for reducing noise and improved fidelity.

It is desirable that the number of control gates N_{gates} needed to form and operate the quantum processor is scaled as N_{gates}∝\sqrt{N_{qubits}}, here N_{qubits} is the number of qubits, which allows for scalability of the quantum circuit, which is achievable by the methods described above.

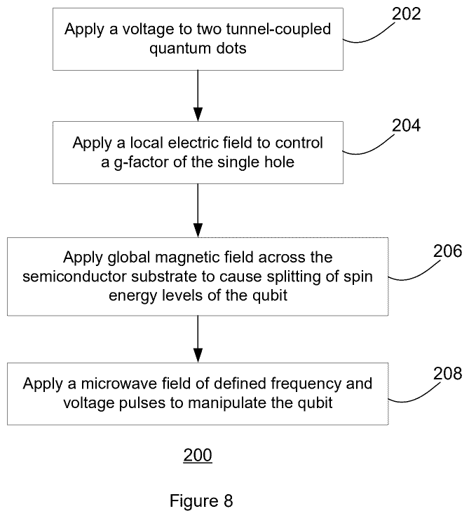

FIG. 8 shows a flowchart 200 with example steps of a method of controlling a hole spin qubit in a semi-conductor substrate, the hole spin qubit comprising two tunnel-coupled QDs. In step 202, a voltage is applied to a first plurality of gates to form the two tunnel-coupled QDs comprising a first QD confining a single hole and an empty second QD configured to affect the spin state of the single hole and configured for readout of the spin state of the single hole. In step 204, a local electric field is applied to control a g-factor of the single hole.

In step 206, a global magnetic field is applied across the semiconductor substrate to cause splitting of spin energy levels of the single hole. In step 208, a microwave field of defined frequency is applied to the first plurality of gates and voltage pulses of defined amplitude and duration are applied to the second plurality of gates to manipulate the single hole's spin at the main frequency of EDSR or its sub-harmonics.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Accordingly, the above description of example implementations does not define or constrain this disclosure. Other changes, substitutions, and alterations are also possible without departing from the spirit and scope of this disclosure.

### REFERENCES

1. D. Loss and D. P. DiVincenzo, “Quantum computation with quantum dots,” Physical Review A (Atomic, Molecular, and Optical Physics), vol. 57, no. 1, pp. 120-126, 1998.
2. F. H. L. Koppens, C. Buizert, K. J. Tielrooij, I. T. Vink, K. C. Nowack, T. Meunier, L. P. Kouwenhoven and L. M. K. Vandersypen, “Driven coherent oscillations of a single electron spin in a quantum dot,” Nature, vol. 442, no. 7104, pp. 766-771, 2006.
3. J. R. Petta, A. C. Johnson, J. M. Taylor, E. A. Laird, A. Yacoby, M. D. Lukin, C. M. Marcus, M. P. Hanson and A. C. Gossard, “Coherent Manipulation of Coupled Electron Spins in Semiconductor Quantum Dots,” Science, vol. 309, no. 5744, pp. 2180-2184, 2005.
4. E. Kawakami, P. Scarlino, D. R. Ward, F. R. Braakman, D. E. Savage, M. G. Lagally, M. Friesen, S. N. Coppersmith, M. A. Eriksson and L. M. K. Vandersypen, “Electrical control of a long-lived spin qubit in a Si/SiGe quantum dot,” Nat Nano, vol. 9, no. 9, pp. 666-670, 2014.
5. H. Watzinger, J. Kukuka, L. Vukugie, F. Gao, T. Wang, F. Schaffler, J.-J. Zhang and G. Katsaros, “A germanium hole spin qubit,” Nature Communications, vol. 9, no. 1, pp. 3902, 2018.
6. D. Jirovec, A. Hofmann, A. Ballabio, P. M. Mutter, G. Tavani, M. Botifoll, A. Crippa, J. Kukucka, O. Sagi, F. Martins, J. Saez-Mollejo, I. Prieto, M. Borovkov, J. Arbiol, D. Chrastina, G. Isella and G. Katsaros, “A singlet-triplet hole spin qubit in planar Ge,” Nature Materials, vol. 20, no. 8, pp. 1106-1112, 2021.
7. N. W. Hendrickx, W. I. L. Lawrie, M. Russ, F. van Riggelen, S. L. de Snoo, R. N. Schouten, A. Sammak, G. Scappucci and M. Veldhorst, “A four-qubit germanium quantum processor,” Nature, vol. 591, no. 7851, pp. 580-585, 2021.
8. G. Burkard, T. D. Ladd, A. Pan, J. M. Nichol and J. R. Petta, “Semiconductor spin qubits,” Reviews of Modern Physics, vol. 95, no. 2, pp. 025003, 2023.
9. V. Marton, A. Sachrajda, M. Korkusinski, A. Bogan and S. Studenikin, “Coherence Characteristics of a GaAs Single Heavy-Hole Spin Qubit Using a Modified Single-Shot Latching Readout Technique,” Nanomaterials, vol. 13, no. 5, pp. 950, 2023.
10. C. H. Yang, R. C. C. Leon, J. C. C. Hwang, A. Saraiva, T. Tanttu, W. Huang, J. Camirand Lemyre, K. W. Chan, K. Y. Tan, F. E. Hudson, K. M. Itoh, A. Morello, M. Pioro-Ladriere, A. Laucht and A. S. Dzurak, “Operation of a silicon quantum processor unit cell above one kelvin,” Nature, vol. 580, no. 7803, pp. 350-354, 2020.
11. A. Laucht, J. T. Muhonen, F. A. Mohiyaddin, R. Kalra, J. P. Dehollain, S. Freer, F. E. Hudson, M. Veldhorst, R. Rahman, G. Klimeck, K. M. Itoh, D. N. Jamieson, J. C. McCallum, A. S. Dzurak and A. Morello, “Electrically controlling single-spin qubits in a continuous microwave field,” Science Advances, vol. 1, no. 3, pp. e1500022, 2015.
12. J. Yoneda, T. Otsuka, T. Takakura, M. Pioro-Ladriere, R. Brunner, H. Lu, T. Nakajima, T. Obata, A. Noiri, C. J. Palmstrom, A. C. Gossard and S. Tarucha, “Robust micromagnet design for fast electrical manipulations of single spins in quantum dots,” Applied Physics Express, vol. 8, no. 8, pp. 084401, 2015.
13. G. Scappucci, C. Kloeffel, F. A. Zwanenburg, D. Loss, M. Myronov, J.-J. Zhang, S. De Franceschi, G. Katsaros and M. Veldhorst, “The germanium quantum information route,” Nature Reviews Materials, vol. 6, pp. 926-943, 2021.
14. M. Myronov, J. Kycia, P. Waldron, W. Jiang, P. Barrios, A. Bogan, P. Coleridge and S. Studenikin, “Holes Outperform Electrons in Group IV Semiconductor Materials,” Small Science, vol. 3, pp. 2200094, 2023.
15. D. V. Khomitsky, M. V. Bastrakova, V. O. Munyaev, N. A. Zaprudnov and S. A. Studenikin, “Controllable single spin evolution at sub-harmonics of electric dipole spin resonance enhanced by four-level Landau-Zener-Stuckelberg-Majorana interference,” Physical Review B, vol. (submitted), 2023.
16. I. Seidler, T. Struck, R. Xue, N. Focke, S. Trellenkamp, H. Bluhm and L. R. Schreiber, “Conveyor-mode single-electron shuttling in Si/SiGe for a scalable quantum computing architecture,” npj Quantum Information, vol. 8, no. 1, pp. 100, 2022. https://doi.org/10.1038/s41534-022-00615-2
17. Studenikin, et al. “Enhanced charge detection of spin qubit readout via an intermediate state,” Applied Physics Letters 2012, 101 (23), 233101-233103. http://dx.doi.org/10.1063/1.4749281

1. A qubit formed in a semiconductor substrate, the qubit comprising:
two tunnel-coupled quantum dots (CQD) comprising a first quantum dot configured to confine a single hole and a second quantum dot configured to stimulate spin transitions in the first quantum dot;
a first plurality of gates configured to create a plurality of confinement potential regions, the first plurality of gates further configured to create a CQD array containing the qubits; and
wherein the CQD array is formed within the semiconductor substrate;
a second plurality of conducting gate electrodes for applying voltages to the first quantum dot of the CQD, wherein a first set of conducting gate electrodes and a second set of conducting gate electrodes of the second plurality of conducting gate electrodes are connected to split control gates of the first quantum dot in each qubit, wherein the first set of conducting gate electrodes and the second set of conducting gate electrodes of the second plurality of gate electrodes configured to apply an electric field to the first quantum dot of CQD to control the g-factor of the single hole;
the qubit is configured to have its spin energy levels split upon application of a global magnetic field applied across the semiconductor substrate;
the first plurality of electrodes configured to apply a microwave field; and
the qubit is configured to be manipulated in the presence of microwave field upon application of voltage pulses applied to a select set of gate electrodes of the second plurality of gate electrodes in the presence of a microwave field.

2. The qubit of claim 1, wherein the second quantum dot serves as a non-linear auxiliary element to stimulate spin transitions in the first quantum dot at least one of a fundamental EDSR frequency and sub-harmonics of the fundamental EDSR frequency.

3. The qubit of claim 1, wherein the magnitude of spin energy splitting of the individual qubit is defined by a product of the global magnetic field and the electrically tunable effective g-factor.

4. The qubit of claim 3, wherein the magnitude of spin energy splitting is multiple times larger than a photon energy of the microwave field used for qubit manipulation.

5. The qubit of claim 4, wherein tuning the g-factor comprises applying predetermined constant and pulsed voltages to the first set of conducting gate electrodes and the second set of conducting gate electrodes of the second plurality of conducting gate electrodes.

6. The qubit of claim 5, further comprising connecting a select set of gate electrodes of the first plurality of conducting gate electrodes placed proximate to the qubit to read out the qubit states.

7. The qubit of claim 1, wherein the semiconductor substrate is compressively strained germanium on silicon (cs-GoS).

8. A method of controlling a hole spin qubit in a semiconductor substrate, the method comprising:
applying a voltages to a first plurality of gates to form two tunnel-coupled quantum dots (CQD) comprising a first quantum dot confining a single hole and a second quantum dot configured to stimulate spin transitions in the first quantum dot and configured for readout of a spin qubit state in the first quantum dot;
applying a local electric field to control a g-factor of the single hole;
applying global magnetic field across the semiconductor substrate to cause of spin energy levels of the spin qubit; and
applying a microwave field of defined frequency and voltage pulses to manipulate the qubit.

9. The method of claim 8, wherein the second quantum dot serves as a non-linear auxiliary element to stimulate spin transitions in the first quantum dot at least one of a fundamental EDSR frequency and sub-harmonics of the fundamental EDSR frequency.

10. The method of claim 8, wherein the magnitude of spin energy splitting of the qubit is defined by a product of the global magnetic field and the electrically tunable effective g-factor.

11. The method of claim 8, wherein the magnitude of spin energy splitting is multiple times larger than a photon energy of the microwave field used for qubit manipulation.

12. The method of claim 8, further comprising connecting a first plurality of conducting gate electrodes placed proximate to the qubit to read out the qubit states.

13. The method of claim 8, wherein tuning the g-factor comprises applying predetermined constant and pulsed voltages to a first set of conducting gate electrodes and a second set of electrodes of a second plurality of gate electrodes.

14. The method of claim 8, wherein the semiconductor substrate is compressively strained germanium on silicon (cs-GoS).

15. An array of addressable hole spin qubits in a semiconductor substrate, the array comprising:
each qubit comprising two tunnel-coupled quantum dots (CQD), wherein a first quantum dot configured to confine a single hole and a second quantum dot configured to affect a spin of the single hole, and wherein a plurality of confinement potential regions is created by a first plurality of gates configured to contain the qubits;
a second plurality of conducting gate electrodes for applying voltages to the first quantum dot of the CQD, wherein a first set of conducting gate electrodes and a second set of conducting gate electrodes of the second plurality of conducting gate electrodes are connected to split control gates of the first quantum dot in each qubit, wherein the first set of conducting gate electrodes and the second set of conducting gate electrodes of the second plurality of gate electrodes configured to apply an electric field to the first quantum dot of CQD to control the g-factor of the single hole;
the qubit is configured to have its spin energy levels split upon application of a global magnetic field applied across the semiconductor substrate;
the first plurality of electrodes configured to apply a microwave field; and
the qubit is configured to be manipulated in the presence of the microwave field upon application of voltage pulses applied to a select set of gate electrodes of the second plurality of gate electrodes.

16. The array of claim 15, wherein a unique value is assignable to the effective g-factor based on predetermined constant and/or pulsed voltages applied to a select set of the first set of conducting gate electrodes and the second set of conducting gate electrodes of the second plurality of conducting gate electrodes.

17. The array of claim 16, wherein the magnitude of spin energy splitting of the qubit is defined by a product of the global magnetic field and the electrically tunable effective g-factor.

18. The array of claim 17, wherein the magnitude of spin energy splitting is multiple times larger than a photon energy of the microwave field for qubit manipulation protocols.

19. The array of claim 18, further comprising connecting select gates of the first plurality of conducting gate electrodes placed proximate to the qubit to read out the qubit states after spin manipulations and implement quantum-computing algorithms.

20. The array of claim 15, wherein the semiconductor substrate is compressively strained germanium on silicon (cs-GoS).

21. The array of claim 20, wherein the qubit array is linear.

22. The array of claim 20, wherein the qubit array is two-dimensional.
